(19) United States
(12) Patent Application Publication
(10) Pub. No.: US 2016/0204383 A1
(43) Pub. Date: Jul. 14, 2016

(54) LIGHT EMITTING DEVICE

(71) Applicants: Pioneer Corporation, Kawasaki-shi, Kanagawa (JP); Tohoku Pioneer Corporation, Tendo-shi, Yamagata (JP)

(72) Inventors: Kenichi OKUYAMA, Yonezawa-shi, Yamagata (JP); Koji FUJITA, Yonezawa-shi, Yamagata (JP)

(21) Appl. No.: 14/913,792

(22) PCT Filed: Sep. 11, 2013
(86) PCT No.: PCT/JP2013/074539

§ 371 Date: Feb. 23, 2016

(51) Int. Cl. H01L 51/52; G09F 13/22; H01L 27/32; F21V 7/00; H01L 51/00

(52) U.S. Cl. CPC H01L 51/5271; F21V 7/0066; H01L 51/0096; H01L 51/5284; H01L 27/3204; H01L 27/3202; H01L 27/3239; G09F 13/22; F21Y 2101/02; H01L 2251/558; G09F 2013/222

(57) ABSTRACT

A light emitting device (10) includes a substrate (100), a plurality of light emitting regions (101), and a light shielding layer (200). The plurality of light emitting regions (101) are provided on a first surface (for example, lower surface of FIG. 2) side of the substrate (100). The light shielding layer (200) is provided on a second surface side (for example, upper surface of FIG. 2) of the substrate (100). As shown in FIG. 2, the light shielding layer (200) is located between the plurality of light emitting regions (101) when seen from a direction perpendicular to the substrate (100). A light absorbing layer (204) is provided on a surface of the light shielding layer (200) which faces the substrate (100).

### TECHNICAL FIELD

The present invention relates to a light emitting device.

### BACKGROUND ART

There is visibility, for example, clearness of the edges of a pattern, or a feature capable of recognizing only a displayed pattern, as one of the characteristics required in alight emitting device that displays a predetermined pattern. Patent Document 1 discloses that a light shielding film is provided on a light emission surface of a light emitting device in order to improve visibility. Specifically, Patent Document 1 is a technique relating to a liquid crystal panel. The light shielding layer is provided on the surface of the liquid crystal panel on the light emission surface side. This light shielding layer is provided with a plurality of openings for forming pixels.

In addition, Patent Document 2 discloses that a light-shielding mask is provided in an optical device using an organic EL element. Specifically, this optical device is configured such that the organic EL element is formed on a transparent substrate, and a surface of a transparent substrate which has the organic EL element formed thereon is sealed by a sealing member. The light-shielding mask is formed in a region of the sealing member which overlaps the organic EL element.

### RELATED DOCUMENTS

### Patent Documents

[Patent Document 1] Japanese Unexamined Patent Application Publication No. 2005-122101

[Patent Document 2] Japanese Unexamined Patent Application Publication No. 2008-129042

### SUMMARY OF THE INVENTION

The inventor has examined an improvement in the visibility of light emitted from each light emitting region, in a light emitting device including a plurality of light emitting regions. There is a method of providing a light shielding film in a region of a light emission surface of the light emitting device which is located between a plurality of light emitting regions, as one of the methods of improving the visibility of such a light emitting device. However, a material used as the light shielding film generally has a high reflectance of visible light in many cases. For this reason, when a portion of light from a certain light emitting region proceeds obliquely toward the light shielding film, the light is reflected by the light shielding film. In this case, at least a portion of the reflected light is reflect by a light emitting region located next to a light emitting region which is emitting light, and is emitted to the outside. When the light emitting region located next thereto is a light emitting region that is not originally emitting light, the occurrence of such reflection causes even the light emitting region which is not originally emitting light to seem to emit light. In this case, the visibility of light emitted from each light emitting region decreases.

The invention that solves this problem includes an example of an improvement in visibility in a light emitting device that displays a predetermined pattern.

According to the invention of claim 1, there is provided a light emitting device including: a substrate; a plurality of light emitting regions which are provided on a first surface side of the substrate; a light shielding layer, provided on a second surface side of the substrate, which is located between the plurality of light emitting regions when seen from a direction perpendicular to the substrate; and a light absorbing layer which is provided on a surface of the light shielding layer which faces the substrate.

### BRIEF DESCRIPTION OF THE DRAWINGS

The above mentioned objects, other objects, features and advantages will be made clearer from the preferred embodiment described below, and the following accompanying drawings.

FIG. 1 is a plan view illustrating a light emitting device according to an embodiment.

FIG. 2 is a cross-sectional view taken along line A-A of FIG. 1.

FIG. 3 is a diagram illustrating a modification example of FIG. 2.

FIG. 4 is a cross-sectional view illustrating a method of forming a light shielding layer.

FIG. 5 is a cross-sectional view illustrating a configuration of a light emitting device according to a comparative example.

FIG. 6 is a cross-sectional view illustrating a function of a light absorbing layer in the light emitting device according to the embodiment.

FIG. 7 is a cross-sectional view illustrating a configuration of a light emitting device according to an example.

FIG. 8 is a diagram illustrating a method of manufacturing the light emitting device according to the example.

FIG. 9 is a diagram illustrating a method of manufacturing the light emitting device according to the example.

FIG. 10 is a diagram illustrating a method of manufacturing the light emitting device according to the example.

### DESCRIPTION OF EMBODIMENTS

Hereinafter, an embodiment of the present invention will be described with reference to the accompanying drawings. In all the drawings, like elements are referenced by like reference numerals and the descriptions thereof will not be repeated.

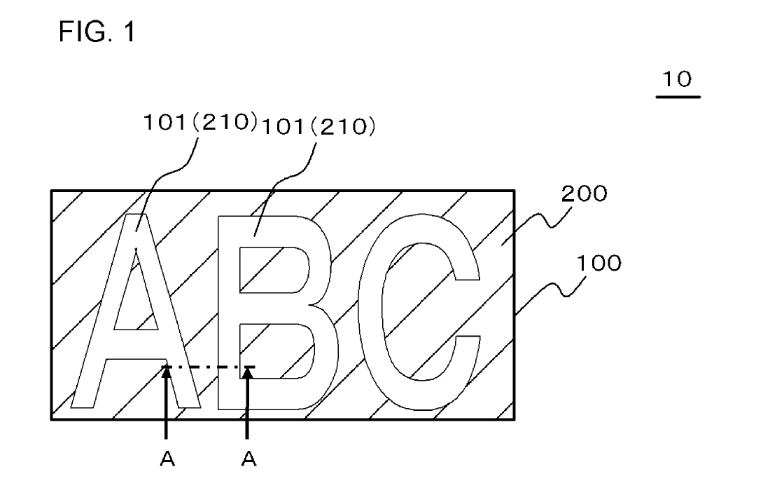

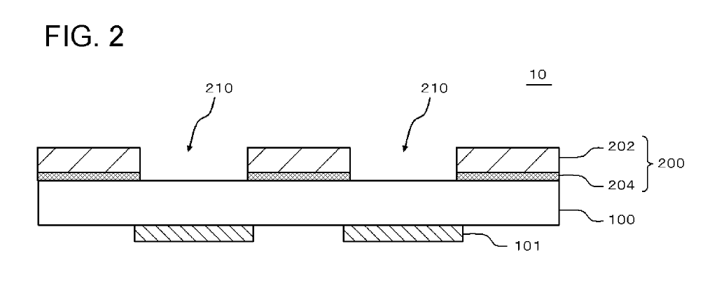

FIG. 1 is a plan view illustrating a light emitting device 10 according to an embodiment. FIG. 2 is a cross-sectional view taken along line A-A of FIG. 1. The light emitting device 10 includes a substrate 100, a plurality of light emitting regions 101, and a light shielding layer 200. The plurality of light emitting regions 101 are provided on a first surface (for example, lower surface of FIG. 2) side of the substrate 100. The light shielding layer 200 is provided on a second surface side (for example, upper surface of FIG. 2) of the substrate 100. As shown in FIG. 2, the light shielding layer 200 is located between the plurality of light emitting regions 101 when seen from a direction perpendicular to the substrate 100. The light shielding layer 200 is formed of a plurality of layers, and a layer on the substrate 100 side has a reflectance lower than that of a layer located thereon. Specifically, a light absorbing layer 204 is provided on a surface of the light shielding layer 200 which faces the substrate 100. As a preferred example of the light absorbing layer 204, light is absorbed, and a transparent layer is not included. The light emitting device 10 is used for displaying characters, symbols or the like, for example, in an optical device. Hereinafter, a detailed description will be given.

The substrate 100 is formed of a material having a light-transmissive property with respect to light which is emitted by the light emitting region 101. The substrate 100 may be a glass substrate, and may be a resin substrate. In addition, when the substrate 100 is thin to some extent, the substrate 100 has flexibility.

For example, each of light emitting elements independent of each other is formed in each of the light emitting regions 101. The light emitting element is, for example, an organic EL element, but may be other spontaneous light emitting elements such as an LED. The light emitting region 101 has planar shapes (for example, character, numeral, and/or symbol) different from each other, for example, as shown in FIG. 1.

The light shielding layer 200 has a plurality of layers laminated therein as described above. A light reflection layer 202 and the light absorbing layer 204 are included in the plurality of layers. In the example shown in FIG. 2, the light shielding layer 200 has a configuration in which the light absorbing layer 204 and the light reflection layer 202 are laminated in this order on the second surface side of the substrate 100. The light reflection layer 202 has a function of shielding visible light (for example, light which is emitted by the light emitting region 101). The light reflection layer 202 is formed of, for example, a metal such as Cr, and the thickness thereof is, for example, equal to or greater than 50 μm and equal to or less than 200 μm. The light absorbing layer 204 is formed of a material having a lower reflectance of light with respect to light emitted by the light emitting region 101 than that of the light reflection layer 202. When the light reflection layer 202 is formed of a metal, the light absorbing layer 204 is formed of an oxide of this metal (for example, chromium oxide). Meanwhile, the light absorbing layer 204 is formed to be thinner than the light reflection layer 202. The thickness of the light absorbing layer 204 is, for example, equal to or less than the thickness of the light reflection layer 202. However, the thickness of the light absorbing layer 204 may be equal to or greater than the thickness of the light reflection layer 202.

As described above, the light shielding layer 200 is located between the plurality of light emitting regions 101 when seen from the direction perpendicular to the substrate 100. Specifically, the light shielding layer 200 includes a plurality of openings 210. The plurality of openings 210 overlap different ones of the light emitting regions 101 when seen from the direction perpendicular to the substrate 100, and have the same shape as that of the overlapping light emitting regions 101. For this reason, the light shielding layer 200 is provided, and thus the edge of a pattern shown by the light emission of the light emitting region 101 becomes sharp. Therefore, the visibility of a pattern shown by the light emitting device 10 is improved.

Meanwhile, when seen from the direction perpendicular to the substrate 100, each of the openings 210 may be slightly smaller than the light emitting region 101. In this case, the edge of the opening 210 is located inside the light emitting region 101. With this configuration, even when positional displacement occurs between the light emitting region 101 and the light shielding layer 200, the edge of the light shielding layer 200 overlaps the light emitting region 101, and the visibility of the light emitting device 10 does not decrease. Meanwhile, the width of a portion in which the light shielding layer 200 and the light emitting region 101 overlap each other is, for example, equal to or greater than 5 μm and equal to or less than 40 μm.

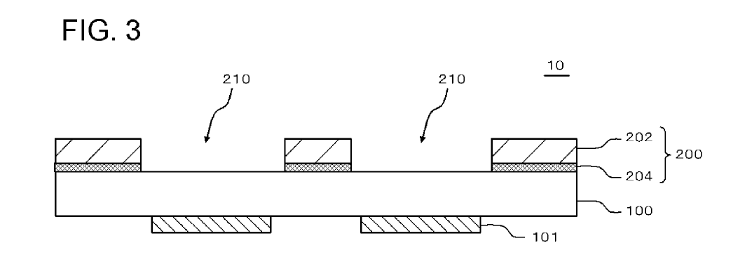

On the contrary, as shown in FIG. 3, each of the openings 210 may be slightly larger than the light emitting region 101. In this case, even when the light emitting device 10 is seen in a slightly oblique view, light from the light emitting device 10 can be recognized.

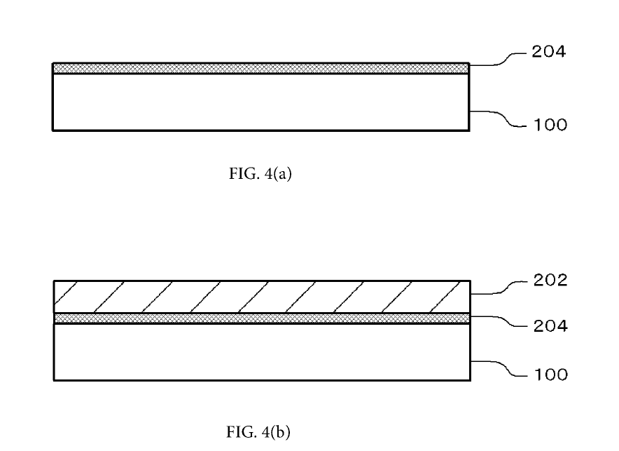

FIG. 4 is a cross-sectional view illustrating a method of forming the light shielding layer 200. Meanwhile, in the drawing, the light emitting region 101 is not shown. However, before the light shielding layer 200 is formed, all of the light emitting regions 101 may not be formed, and at least some of layers of the light emitting regions 101 may be formed.

First, as shown in FIG. 4(a), the light absorbing layer 204 is formed on the substrate 100. Next, as shown in FIG. 4(b), the light reflection layer 202 is formed on the light absorbing layer 204. The light absorbing layer 204 and the light reflection layer 202 are formed using, for example, a vapor phase film formation method such as a sputtering method, a vapor deposition method, or a CVD method. Meanwhile, when the light absorbing layer 204 is formed of an oxide of a metal for forming the light reflection layer 202, it is preferable that the light reflection layer 202 and the light absorbing layer 204 are formed in the same processing chamber. In this case, first, film formation is performed in the processing chamber while an oxidizing agent (for example, oxygen gas) is introduced into the processing chamber, and then the introduction of the oxidizing agent is stopped while continuing the film formation, thereby allowing the light absorbing layer 204 and the light reflection layer 202 to be formed continuously.

Thereafter, a mask pattern (not shown) is formed on the light reflection layer 202, and the light reflection layer 202 and the light absorbing layer 204 are etched using this mask pattern as a mask. Etching performed herein is, for example, wet etching, but may be dry etching. Thereby, the light reflection layer 202 and the light absorbing layer 204 are formed in a predetermined pattern. Meanwhile, when the light absorbing layer 204 is an oxide film of a metal for forming the light reflection layer 202, the light reflection layer 202 and light absorbing layer 204 can be collectively etched in the same etching conditions (for example, the same etching solution).

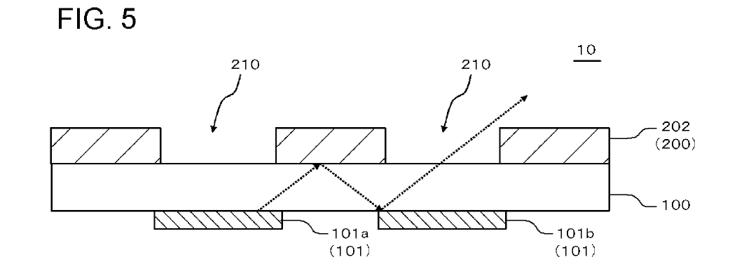

FIG. 5 is a diagram illustrating a configuration of the light emitting device 10 according to a comparative example, and corresponds to FIG. 2 in the embodiment. The light emitting device 10 has the same configuration as that of the light emitting device 10 according to the embodiment, except that the light shielding layer 200 does not include the light absorbing layer 204. A case is considered in which a certain light emitting region 101a (left light emitting region 101 in FIG. 5) is emitting light, and a light emitting region 101b (right light emitting region 101 in FIG. 5) located next thereto is not emitting light. Generally, light emitted by a light emitting element spreads at a certain angle. For this reason, a portion of light emitted from the light emitting region 101a is reflected by the light reflection layer 202, is further reflected by the light emitting region 101b, and then is radiated to the outside of the light emitting device 10. In this case, regardless of the light emitting region 101b not emitting light, the light emitting region 101b seems to emit light slightly. In this case, the visibility of the light emitting device 10 decreases.

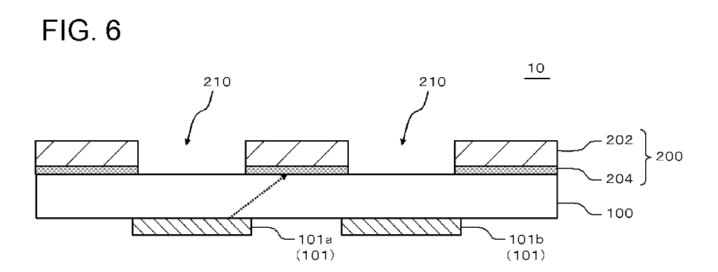

On the other hand, in the present embodiment, the light absorbing layer 204 is formed on a surface of the light shielding layer 200 which faces the substrate 100. The light absorbing layer 204 has a reflectance of light lower than that of the light reflection layer 202. Therefore, as shown in FIG. 6, even when a portion of light emitted from the light emitting region 101a is incident on the light shielding layer 200, the amount of light reflected toward the light emitting region 101b from the light shielding layer 200 is reduced, or is substantially eliminated. Therefore, the visibility of the light emitting device 10 is improved.

### EXAMPLE

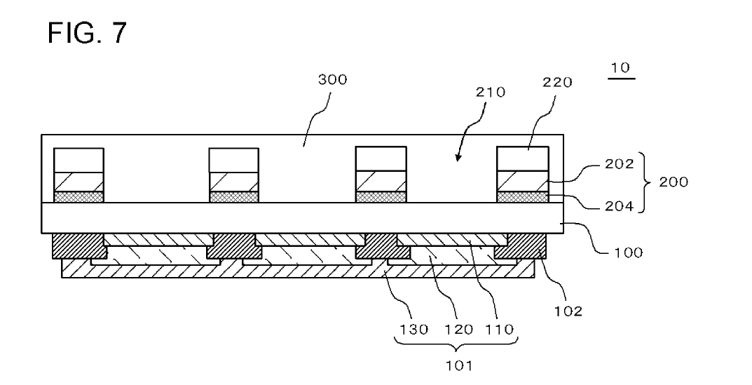

FIG. 7 is a cross-sectional view illustrating a configuration of a light emitting device 10 according to an example. The light emitting device 10 according to the present example has the same configuration as that of the light emitting device 10 shown in the embodiment, except for the following points.

First, the light emitting region 101 is formed of an organic EL element. Specifically, the light emitting region 101 includes a first electrode 110, an organic layer 120, and a second electrode 130. Meanwhile, other layers may be formed between the respective layers.

The first electrode 110 is formed of a light-transmitting conductive material, for example, an inorganic material such as an indium thin oxide (ITO) or an indium zinc oxide (IZO), or a conductive polymer such as a polythiophene derivative. The second electrode 130 is formed of a material that reflects light, for example, a metal such as an Al electrode.

The organic layer 120 is, for example, a layer in which a hole transport layer, a light emitting layer, and an electron transport layer are laminated. The hole transport layer comes into contact with the first electrode 110, and the electron transport layer comes into contact with the second electrode 130. In this manner, the organic layer 120 is interposed between the first electrode 110 and the second electrode 130. A material of the organic layer 120, for example, a material of the light emitting layer is selected, thereby allowing the color of light emitted by the light emitting region 101 to be set to a desired color.

Meanwhile, a hole injection layer may be formed between the first electrode 110 and the hole transport layer, and an electron injection layer may be formed between the second electrode 130 and the electron transport layer. In addition, not all of the layers mentioned above are required. For example, when the recombination of holes and electrons occur within the electron transport layer, the electron transport layer also has a function of the light emitting layer, and thus the light emitting layer is not required. In addition, at least one of the first electrode 110, the hole injection layer, the hole transport layer, the electron transport layer, the electron injection layer, and the second electrode 130 may be formed using a coating method such as an ink jet method. In addition, an electron injection layer formed of an inorganic material such as LiF may be provided between the organic layer 120 and the second electrode 130.

When seen from the direction perpendicular to the substrate 100, the second electrode 130 is formed between the light emitting regions 101 adjacent to each other. That is, the first electrode 110 and the organic layer 120 are patterned for each of the light emitting regions 101, but the second electrode 130 serves as a common electrode between a plurality of first electrodes 110.

Meanwhile, an insulating layer 102 is formed between the light emitting regions 101 adjacent to each other. Specifically, the first electrode 110 and the organic layer 120 are formed between the insulating layers 102 adjacent to each other. A portion of the organic layer 120 may protrude onto the insulating layer 102. The second electrode 130 is continuously formed on the organic layer 120 and the insulating layer 102. The insulating layer 102 is formed of a photosensitive resin such as a polyimide-based resin, and is formed in a desired pattern by exposure and development. As the insulating layer 102, for example, a positive-type photosensitive resin is used. Meanwhile, the insulating layer 102 may be resins other than a polyimide-based resin, for example, an epoxy-based resin or an acrylic-based resin.

After the insulating layer 102 is formed, the organic layer 120 and the second electrode 130 are formed in this order.

A polarization layer 300 is formed on a surface of the substrate 100 which has the light shielding layer 200 formed thereon. The polarization layer 300 covers the light shielding layer 200. The polarization layer 300 is provided in order to prevent external light incident on the light emitting region from being reflected by the second electrode 130, or preventing the external light from being reflected at the upper surface of the light shielding layer 200. That is, it is possible to improve the quality of the appearance of the light emitting device 10 when the light emitting device 10 is not emitting light. When the polarization layer 300 is formed on the light shielding layer 200, the thickness of the light shielding layer 200 may be set to be equal to or less than 200 nm. When the thickness of the light shielding layer 200 becomes larger, air bubbles are trapped during the attachment of the polarization layer 300 to the substrate 100, and thus the quality of appearance is deteriorated.

In addition, a coating film 220 is formed on a surface of the light reflection layer 202 of the light shielding layer 200 which is opposite to the light absorbing layer 204. The coating film 220 is formed of, for example, a resin such as a resist, or an inorganic material such as a silicon oxide. In a process of manufacturing the light emitting device 10 described later, after the light shielding layer 200 is formed on the second surface of the substrate 100, the substrate 100 may be transported with the second surface side facing downward. In this case, the coating film 220 is provided in order not to damage the light shielding layer 200.

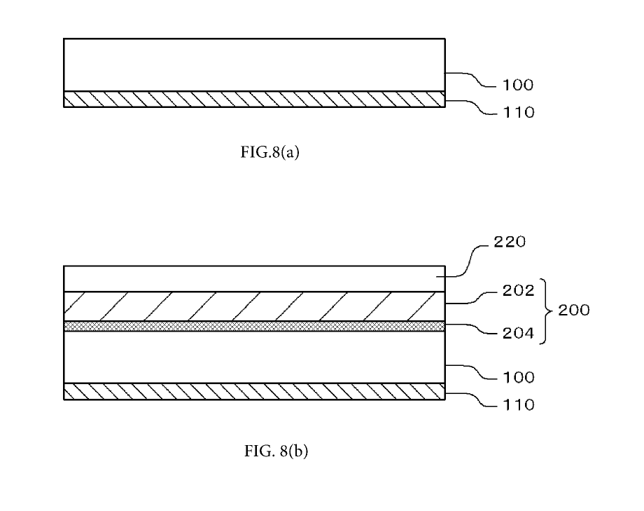

FIGS. 8 to 10 are diagrams illustrating a method of manufacturing the light emitting device 10 in the present example. First, as shown in FIG. 8(a), the first electrode 110 is formed on a surface of the substrate 100 which has the light emitting region 101 formed thereon. At this stage, the first electrode 110 is not patterned. Meanwhile, the first electrode 110 is formed using, for example, a vapor deposition method, a sputtering method, or a CVD method.

Next, as shown in FIG. 8(b), the light absorbing layer 204 and the light reflection layer 202 are formed on a surface of the substrate 100 which is opposite to a surface having the first electrode 110 formed thereon. Next, the coating film 220 is formed on the light reflection layer 202. The coating film 220 is formed using, for example, a coating method.

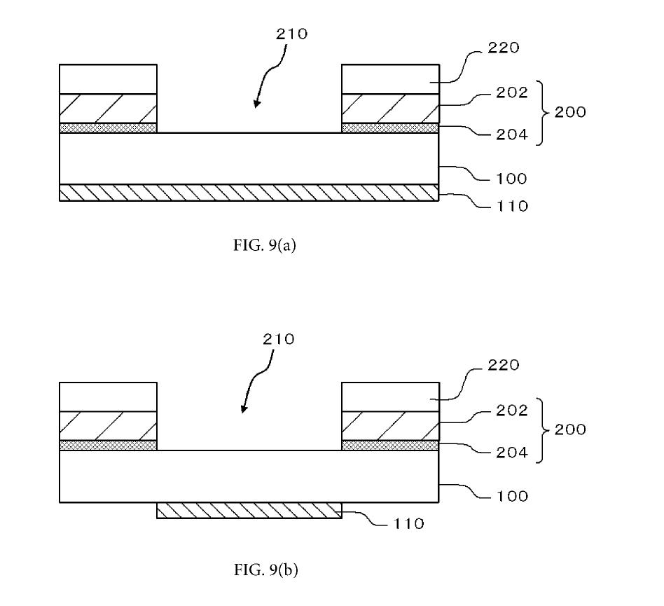

Next, as shown in FIG. 9(a), the light shielding layer 200 and the coating film 220 are patterned, and the opening 210 is formed.

Next, as shown in FIG. 9(b), the first electrode 110 is patterned. This process is performed, for example, by forming a resist pattern on the first electrode 110, and etching the first electrode 110 using the resist pattern as a mask. In addition, in this case, a transport surface serves as the light shielding layer 200, and thus the light shielding layer 200 has a tendency to be damaged. On the other hand, in the present example, the coating film 220 is provided on a surface of the light shielding layer 200 which is opposite to the substrate 100. For this reason, it is possible to suppress damage to the light shielding layer 200.

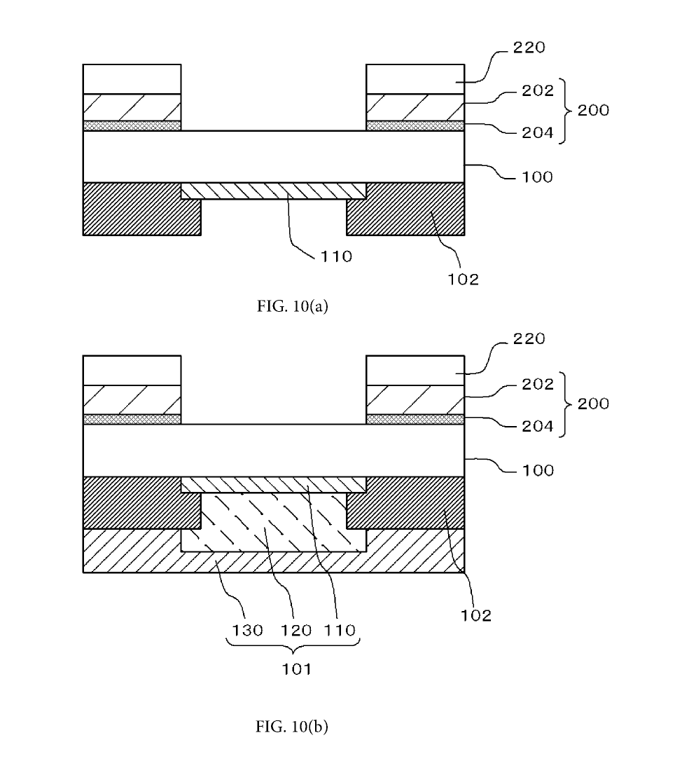

Next, as shown in FIG. 10(a), the insulating layer 102 is formed, and the insulating layer 102 is patterned. When the insulating layer 102 is formed of a photosensitive material, the insulating layer 102 is patterned by exposure and development.

Next, as shown in FIG. 10 (b), the organic layer 120 is formed. Each layer constituting the organic layer 120 may be formed using a vapor deposition method, and may be formed using a coating method such as spray coating, dispenser coating, ink jet, or printing. In addition, at least one of a plurality of layers constituting the organic layer 120 may be formed by methods different from those in which other layers are formed.

Next, the second electrode 130 is formed on the organic layer 120. The second electrode 130 is formed using, for example, a vapor deposition method, a sputtering method, or a CVD method. Thereafter, the polarization layer 300 is formed.

In the present example, as is the case with the embodiment, it is also possible to prevent the visibility of the light emitting device 10 from decreasing.

In addition, in the present example, when seen from the direction perpendicular to the substrate 100, the second electrode 130 is also formed in a region located between the light emitting regions 101. Therefore, when the light reflection layer 202 reflects light from the organic layer 120, there is a high probability of this reflected light being reflected by the second electrode 130. In this case, the visibility of the light emitting device 10 particularly has a tendency to decrease. On the other hand, in the present example, the light absorbing layer 204 is formed on a surface of the light reflection layer 202 which faces the substrate 100. Therefore, even when the second electrode 130 is formed between the light emitting regions 101 adjacent to each other, it is possible to prevent the visibility of the light emitting device 10 from decreasing.

As described above, although the embodiment and examples have been set forth with reference to the accompanying drawings, they are merely illustrative of the present invention, and various configurations other than those stated above can be adopted.

1. A light emitting device comprising:
a substrate;
a plurality of light emitting regions which are provided on a first surface side the substrate; and
a light shielding layer, provided on a second surface side of the substrate, which is located between the plurality of light emitting regions when seen from a direction perpendicular to the substrate,
wherein the light shielding layer is formed of a plurality of layers, and a layer on the substrate side has a reflectance lower than that of a layer located thereon.

2. The light emitting device according to claim 1, wherein the light shielding layer is covered with a coating film.

3. The light emitting device according to claim 2, wherein the layer located on the layer on the substrate side is formed of a metal, and
the layer on the substrate side is formed of an oxide of the metal.

4. The light emitting device according to claim 3, wherein each of the plurality of light emitting regions includes:
a first electrode;
a second electrode which is provided on an opposite side to the substrate with the first electrode interposed therebetween; and
an organic layer which is located between the first electrode and the second electrode.

5. The light emitting device according to claim 4, wherein when seen from the direction perpendicular to the substrate, the second electrode is also formed in a region located between the plurality of light emitting regions.

6. The light emitting device according to claim 1, wherein a thickness of the light shielding layer is equal to or less than 200 nm.
